(19) United States
(12) Patent Application Publication
(10) Pub. No.: US 2023/0371167 A1
(43) Pub. Date: Nov. 16, 2023

(54) SUBSTRATE FOR AN ELECTRONIC CHIP

(71) Applicants: CENTRE NATIONAL D'ETUDES SPATIALES, PARIS CEDEX 01 (FR); CENTRE NATIONAL DE LA RECHERCHE SCIENTIFIQUE, PARIS (FR); Institut Polytechnique de Grenoble, GRENOBLE (FR); UNIVERSITE GRENOBLE ALPES, SAINT MARTIN D'HERES (FR); Université de Chambéry - Université Savoie Mont Blanc, CHAMBERY CEDEX (FR)

(72) Inventors: Pascal FEBVRE, LOISIEUX (FR); Ugur YILMAZ, AIX LES BAINS (FR)

(21) Appl. No.: 18/246,933

(22) PCT Filed: Oct. 18, 2021
(86) PCT No.: PCT/EP2021/078761

§ 371 Date: Mar. 28, 2023

(30) Foreign Application Priority Data
Oct. 21, 2020 (FR) 20/10777

(51) Int. Cl. H05K 1/02; H01L 23/00; H05K 1/14

(52) U.S. Cl. CPC H05K 1/0206; H01L 24/48; H01L 24/08; H05K 1/144; H05K 2201/041; H01L 2224/48106; H01L 2224/48157; H01L 2224/08235; H01L 2924/20101

(57) ABSTRACT

The present description concerns a support (108) for an electronic die (110), comprising: a first printed circuit board (300); a first conductive region (310), intended to receive the die, located on a first surface (108i) of the first board; and a second conductive region (320), intended to receive a thermal connector (200), located on a second surface (108s) of the first board, opposite to the first surface, the first region being connected to the second region by at least one through conductive via (330), located vertically in line with the first region.

### CROSS-REFERENCES TO RELATED APPLICATIONS

This application claims the benefit of PCT/EP2021/078761, filed Oct. 18, 2021, which claims the benefit of French Patent Application No. 20/10777, filed Oct. 21, 2020, and incorporates the disclosure of each application by reference.

### TECHNICAL BACKGROUND

The present disclosure generally concerns electronic devices and, more particularly, supports for electronic dies.

### PRIOR ART

Supports enabling to mechanical hold and to cool an electronic die, for example, a die adapted to operating in a cryogenic environment, are known. Such supports are often expensive, bulky, and provided with a restricted number of contacting elements of the die.

### SUMMARY

There is a need to improve existing electronic die supports.

An embodiment overcomes all or part of the disadvantages of known electronic die supports.

An embodiment provides a support for an electronic die, comprising:
a first printed circuit board;
a first conductive region, intended to receive the die, located on a first surface of the first board; and
a second conductive region, intended to receive a thermal connector, located on a second surface of the first board, opposite to the first surface,
the first region being connected to the second region by at least one through conductive via, located vertically in line with the first region.

According to an embodiment, the via is filled with a thermally conductive material.

According to an embodiment, the via is hollow and has lateral walls coated with a thermally-conductive material.

According to an embodiment, the die is a die adapted to operating at cryogenic temperatures, preferably a die comprising superconductive circuits.

According to an embodiment, one or a plurality of third conductive regions, preferably four third conductive regions, are interposed between the first region and the second region, the via connecting the third regions to one another.

According to an embodiment:
the first region is formed in a first metallization level, located on the first surface of the first board;
the second region is formed in a second metallization level, located on the second surface of the first board; and
each third region is formed in a third distinct metallization level, located between the first and second surfaces of the first board.

According to an embodiment, stacked metallization levels are separated by an insulating layer.

According to an embodiment, the first region has a surface area of approximately 50 mm².

According to an embodiment, the first board comprises approximately one hundred first elements for contacting the die.

According to an embodiment, the first contacting elements are located on a same side of the first board, with respect to the first region.

According to an embodiment, the first board, of substantially rectangular shape, has a length of approximately 12 cm and a width of approximately 3 cm.

According to an embodiment, the support further comprises at least one second printed circuit board, stacked to the first board.

According to an embodiment, each second board comprises second contacting elements intended to be connected to third contacting elements of the die by conductive wires.

An embodiment provides a system comprising:
at least one support such as described;
at least one electronic die, adapted to operating in a cryogenic environment;
at least one cold source; and
at least one thermal connector, connecting the support to the cold source.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A is a partial simplified cross-section view of an example of cryogenic system of the type to which the described embodiments apply as an example;

FIG. 1B is a partial simplified cross-section view of another example of a cryogenic system of the type to which the described embodiments apply as an example;

FIG. 2 is a partial simplified side view of still another example of a cryogenic system of the type to which the described embodiments apply as an example;

FIG. 3 is a partial simplified cross-section view of an embodiment of an electronic die support;

FIG. 4 is a partial simplified top view of the embodiment of the electronic die support discussed in relation with FIG. 3;

FIG. 5 is another top view of the embodiment of the electronic die support discussed in relation with FIGS. 3 and 4;

FIG. 6 is a partial simplified cross-section view of another embodiment of an electronic die support;

FIG. 7 is a partial simplified top view of the embodiment of the electronic die support discussed in relation with FIG. 6;

FIG. 8 is a partial simplified top view of still another embodiment of an electronic die support; and

FIG. 9 is a cross-section view of the electronic die support of FIG. 8.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the installation and the connection of the dies on these supports are not detailed, the invention being compatible with usual techniques of installation and connection of dies on supports.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,” “right,” etc., or relative positions, such as terms “above,” “under,” “upper,” “lower,” etc., or to terms qualifying directions, such as terms “horizontal,” “vertical,” etc., unless otherwise specified, it is referred to the orientation of the drawings.

Unless specified otherwise, the expressions “around,” “approximately,” “substantially” and “in the order of” signify within 10%, and preferably within 5%.

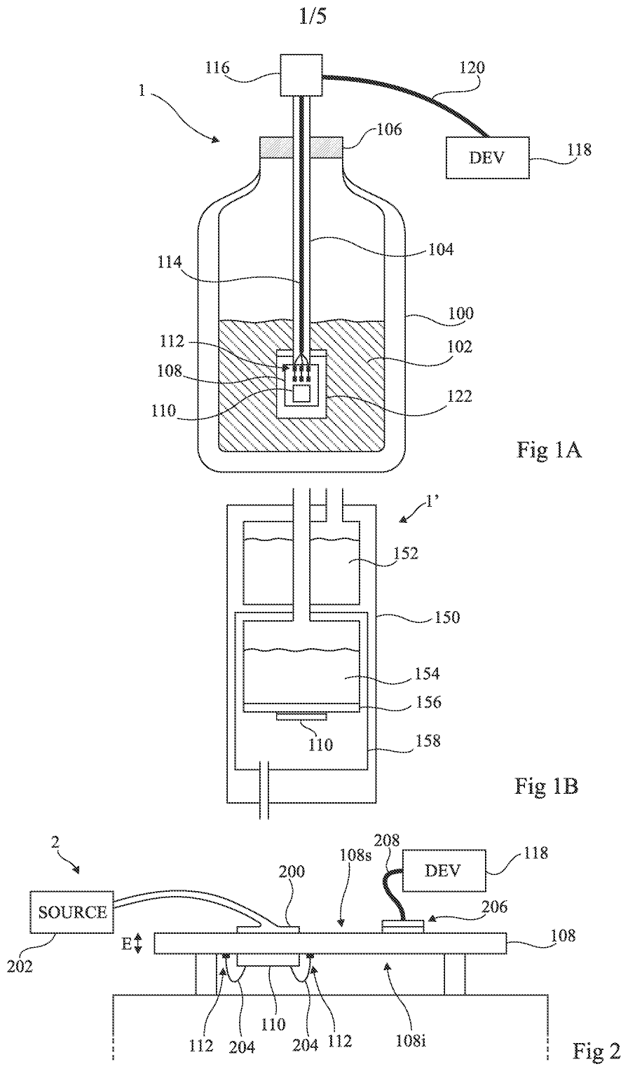

FIG. 1A is a partial simplified cross-section view of an example of a cryogenic system 1 of the type to which the described embodiments apply as an example.

Cryogenic system 1 comprises a cryostat 100, for example a dilution cryostat using two isotopes of helium. Cryostat 100 is, in FIG. 1A, symbolized by a substantially cylindrical double-walled vessel containing a cryogenic fluid 102, liquid helium in this example. A measuring stick 104 penetrates into cryostat 100 through a flange or plug 106 closing an upper opening or upper port of cryostat 100. Flange 106 enables to introduce measuring stick 104 while ensuring a tightness, or limiting a leakage rate, between the inside and the outside of cryostat 100. As an example, cryostat 100 is a dewar vessel.

At a first end of measuring stick 104 (the lower end of stick 104, in FIG. 1A) is attached a support 108 of an electronic die 110. Electronic die 110 is a die adapted to operating at cryogenic temperatures (in other words in a cryogenic environment), preferably a die comprising superconductive circuits.

Support 108 is intended to ensure a plurality of functions. In particular, support 108 enables to:
mechanically hold die 110, in particular during phases of introduction and of removal of measuring stick 104 into and from cryostat 100;
optimally cool die 110, by exposing one or a plurality of surfaces thereof to a cryogenic environment;
couple or connect die 110 to one or a plurality of devices located outside of cryostat 100.

Support 108 comprises contacting elements 112. The elements 112 for contacting die 110 are, in the example of FIG. 1A, connected to a first cable 114. Cable 114 is coupled or connected to a connection package 116 located at a second end of measuring stick 104 (the upper end of stick 104, in FIG. 1A), external to cryostat 100. Connection package 116 is, for example, a junction box comprising terminals (not shown) adapted to the transmission of signals from or towards die 110. In the example of FIG. 1A, measuring stick 104 is hollow. This enables to run cable 114 inside of measuring stick 104. In this example, connection package 116 is connected to an electronic device 118 (DEV) via a second cable 120.

Signals can thus be exchanged between the inside and the outside of cryostat 100. More precisely, as illustrated in FIG. 1A, signals may be exchanged between die 110 and electronic device 118 via:
contacting elements 112;
first cable 114;
connection package 116; and
second cable 120.

The cooling of die 110 is performed by means of a cold source. In the example of FIG. 1A, the cold source is formed by cryogenic fluid 102 (here, liquid helium) contained in cryostat 100. Die 110 may be indirectly cooled, for example by placing support 108 and die 110 inside of an enclosure 122 as shown in FIG. 1A. Enclosure 122, which may contain a partial vacuum, enables to avoid any direct contact of support 108 and of die 110 with cryogenic fluid 102.

As a variant, die 110 is directly cooled. This for example corresponds to a configuration where support 108 is at least partially plunged into cryogenic fluid 102, enclosure 122 then being omitted.

In system 1, the number of elements 112 for contacting die 110 is generally conditioned by dimensions and by a geometry of support 108. The dimensions and the geometry of support 108 are themselves constrained by the dimensions and by a geometry of the upper opening of cryostat 100, closed by flange 106, to enable to freely introduce and remove measuring stick 104.

In a case where the upper opening of cryostat 100 (having substantially circular cross-section, in this example), has a small inner diameter, for example, smaller than 5 cm, the number of elements 112 for contacting die 110 is strongly limited. This is often an issue, in particular when die 110 is a microprocessor exchanging many signals with electronic device 118.

It could have been devised to enlarge the upper opening of cryostat 100 to enable to increase the number of contacting elements 112 of die 110. However, in cryogenic system 1, it is generally aimed at reaching and maintaining close to die 110 a very low temperature, for example in the order of −269° C. (that is, approximately 4.2 K) or in the order of −273.15° C. and −271° C. in a case where the outer pressure of the dewar is decreased by pumping of the cryogenic fluid in the gaseous state, the pumping being performed for example through a hole (not shown) crossing flange 106. It is in particular desired to avoid or to limit any heat exchange capable of occurring, for example, at the level of flange 106, between the inside the outside of cryostat 100, since such exchanges are likely to adversely affect the operation of die 110. It is thus in particularly ascertained that the upper opening of cryostat 100 has as small an exchange surface area, and thus an inner diameter, as possible.

FIG. 1B is a partial simplified cross-section view of another example of a cryogenic system 1′ of the type to which the described embodiments apply as an example.

Conversely to the cryogenic system 1 of FIG. 1A, which provides cooling die 110 by immersion in cryogenic fluid 102, cryogenic system 1′ provides cooling die 110 by conduction.

In the shown example, cryogenic system 1′ comprises a cryostat 150 having the die 110 to be cooled placed therein. Cryostat 150 for example comprises a reservoir 152. Reservoir 152 is for example intended to contain a first cryogenic fluid.

In the shown example, cryostat 150 further comprises another reservoir 154. Reservoir 154 is for example intended to contain a second cryogenic fluid, for example, different from the first cryogenic fluid.

As an example, the first cryogenic fluid is liquid nitrogen and the second cryogenic fluid is liquid helium.

As an example, a decreased saturating vapor pressure of reservoir 154 is obtained by pumping of the second cryogenic fluid in the gaseous state, for example to take advantage of the excellent thermal conductivity properties of superfluid helium below the lambda point. This further enables to decrease the temperature of die 110 with respect to the temperature that would be obtained with no pumping. Similar provisions may be implemented for reservoir 152.

In the orientation of FIG. 1B, a plate 156 is for example in contact with the lower wall of reservoir 154. Plate 156, called cold plate, is for example intended to receive die 110. Plate 156 for example enables to optimize a heat transfer between reservoir 154 and die 110. Plate 156 for example plays the role of a heat conductor. As an example, plate 156 is made of a thermally-conductive material, for example, a metal.

In the shown example, reservoir 154, plate 156, and die 110 are located in a vacuum enclosure 158. Enclosure 158 is for example intended to create a partial vacuum around die 110.

Although this has not been shown in FIG. 1B, cryostat 150 may comprise other elements such as pumps, anti-radiation screens, etc. In particular, the cryostat may for example comprise a helium-3 (³He) reservoir, for example interposed between plate 156 and die 110, or a device enabling to regulate the temperature of die 110 to a value greater than that of plate 156.

FIG. 2 is a partial simplified side view of still another example of a cryogenic system 2 of the type to which the described embodiments apply as an example. The cryogenic system 2 of FIG. 2 has elements common with the cryogenic systems 1 and 1′ of FIGS. 1A and 1B. These elements will not be described again hereafter.

In cryogenic system 2, die 110 is assembled on a first surface 108i of support 108 (the lower surface of support 108, in side view and in cross-section view in FIG. 2). A thermal connector 200 is arranged, opposite die 110, on a second surface 108s of support 108 (the upper surface of support 108, in FIG. 2), opposite to first surface 108i.

Thermal connector 200 is made of at least one thermally-conductive material, that is, a material having a thermal conductivity at room temperature greater than 60 W·m⁻¹·K⁻¹. As an example, thermal connector 200 is made of a metal or of a metal alloy, for example, an alloy of tin and copper. A cold source 202 (SOURCE), enabling to cool die 110, is coupled or connected to thermal connector 200.

In the example of FIG. 2, wire bondings 204 enable to connect the connection pads (not shown) of die 110 to the contacting elements 112 of support 108. An electric connector 206 is coupled, preferably connected, to contacting elements 112. Electric connector 206 is coupled, preferably connected, to electronic device 118 (DEV) via a third cable 208. As illustrated in FIG. 2, signals can be exchanged between die 110 and electronic device 118 via:
connection wires 204;
contacting elements 112;
connector 206; and
cable 208.

In system 2, thermal connector 200 is not in direct contact with die 110. Die 110 is indeed separated from thermal connector 200 by the thickness, noted E, of substrate 108 in side view in FIG. 2. Thickness E causes a thermal resistance between thermal connector 200 and die 110. This thermal resistance, which is all the larger as thickness E is significant and as support 108 is thermally insulating, adversely affects the cooling of die 110 by cold source 202.

It could have been devised to implant thermal connector 200 directly on die 110. This would however have caused significant issues in terms of connection of support 108 to the contacting elements 112 of die 110. It could then also have been devised to decrease the thickness E of support 108. This would however have tended to too significantly fragilizing support 108. This would further adversely affect the signal transmission quality.

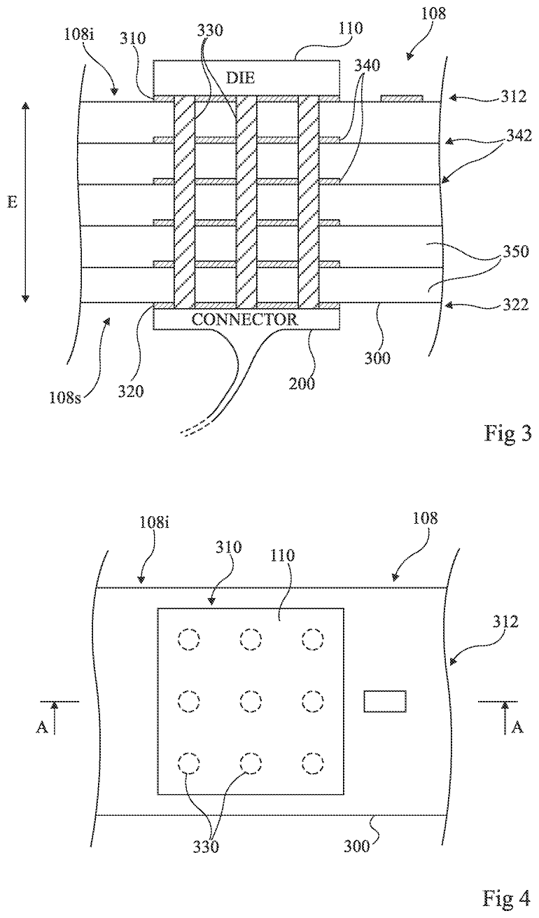

FIG. 3 is a partial simplified cross-section view of an embodiment of electronic die support 108.

According to this embodiment, support 108 comprises a printed circuit board 300. The orientation of FIG. 3 is inverted with respect to that of FIG. 2. In the orientation of FIG. 3:
first surface 108i corresponds to the upper surface of support 108 and to an upper surface of board 300; and
second surface 108s corresponds to the lower surface of support 108 and to a lower surface of board 300.

On the side of surface 108i, board 300 comprises a first conductive region 310 intended to receive die 110 (DIE). Die 110 is, as illustrated in FIG. 3, arranged on top of and in contact with first region 310. First region 310 is preferably formed in a first metallization level 312 located on the surface 108i of board 300. In the orientation of FIG. 3, first metallization level 312 for example corresponds to an upper metallization level of board 300.

On the side of surface 108s, board 300 comprises a second conductive region 320 intended to receive thermal connector 200 (CONNECTOR). Thermal connector 200 is, as illustrated in FIG. 3, arranged on top of and in contact with second region 320. Second region 320 is preferably formed in a second metallization level 322 located on the surface 108s of board 300. Second region 320 faces first region 310. In the orientation of FIG. 3, second metallization level 322 for example corresponds to a lower metallization level of board 300.

According to this embodiment, first region 310 is connected to second region 320 by conductive vias 330 crossing board 300, and thus support 108, across its entire thickness E. Conductive vias 330 are located vertically in line with first region 310 and with second region 320, to form thermal conduction paths having a length substantially equal to the thickness E of board 300.

Conductive vias 330 are for example integrally filled with at least one thermally-conductive material, preferably a thermally- and electrically-conductive material, for example, copper. As a variant, only the inner walls of conductive vias 330 are coated with the thermally-conductive material, for example, in a case where support 108 is immersed in the cryogenic fluid. Thermal connector 200 then for example has through ports, aligned with respect to hollow conductive vias 330, to allow a circulation of the cryogenic fluid inside of vias 330. Heat exchanges are thus further improved by enabling the cryogenic fluid to implement a thermal convection.

Still according to this embodiment, printed circuit board 300 comprises at least one third conductive region 340, preferably four third regions 340, interposed between first region 310 and second region 320. Third region(s) 340 are respectively formed in third intermediate metallization levels 342, located between the surface 108i and the surface 108s of board 300. Third regions 340 are connected to one another by conductive vias 330. Thus, as illustrated in FIG. 3, conductive vias 330 connect together the first, second, and third regions 310, 320, and 340 of board 300.

The first, second, and third metallization levels 312, 322, and 342 are separated from one another by electrically-insulating layers 350. In other words, two stacked metallization levels, and thus two stacked regions, are separated by an insulating layer 350.

One of the advantages of the embodiment discussed in relation with FIG. 3 is to allow an improved thermal conduction between die 110 and thermal connector 200, and a thermal convection by the cryogenic fluid in the case of hollow vias 330, in particular as compared with a support 108 which would comprise no conductive via 330. Die 110 may thus be more efficiently cooled by cold source 202 (not shown in FIG. 3) connected to thermal connected 200.

FIG. 4 is a partial simplified top view of the embodiment of the electronic die support 108 discussed in relation with FIG. 3. FIG. 3 for example corresponds to a cross-section along plane AA of FIG. 4.

According to a preferred embodiment, the first region 310 of first metallization level 312 located on the surface 108i of support 108 has, in top view in FIG. 4, dimensions approximately equal to those of die 110. Still according to this preferred embodiment, first region 310 is square-shaped and has a side length of approximately 7 mm. Region 310 thus occupies a surface area of approximately 50 mm² at the surface of board 300.

The distribution of conductive vias 330 may be designed to optimize the cooling of die 110. In particular, conductive vias 330 may advantageously be located under areas of die 110 which are desired to be preferentially cooled. The number and the geometry of conductive vias 330 may further be adjusted according to a thermal performance to be achieved.

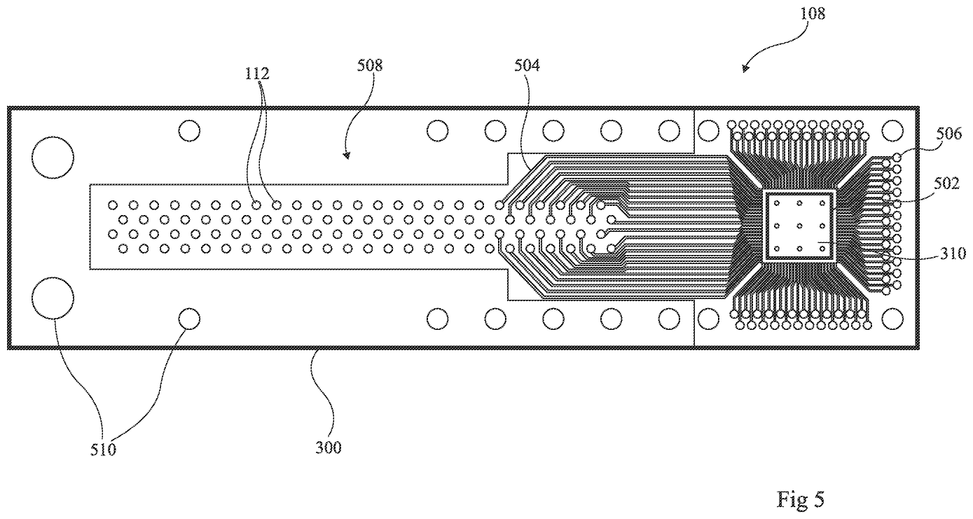

FIG. 5 is another top view of the embodiment of electronic die support 108 discussed in relation with FIGS. 3 and 4.

According to this embodiment, support 108 has, in top view in FIG. 5, a substantially rectangular shape. Support 108 preferably has a length of approximately 12 cm and a width of approximately 3 cm.

Support 108 comprises the contacting elements 112 of a die 110 (not shown in FIG. 5). Support 108 preferably comprises approximately one hundred contacting elements 112. Each contacting element 112 is coupled, preferably connected, to a connection pad 502 located at the periphery of the first region 310 intended to receive the die. Conductive tracks 504 and through conductive vias 506 enable to connect each connection pad 502 to a contacting element 112.

As an example, through conductive vias 506 are entirely filled with a metal, for example, copper. As a variant, through conductive vias 506 are hollow and their lateral walls are coated with a metal, for example, copper.

According to a preferred embodiment, contacting elements 112 are all arranged on a same side of board 300 with respect to first region 310 (on the left-hand side with respect to first region 310, in FIG. 5). In FIG. 5, some of connection pads 502 are connected to contacting elements 112 by conductive tracks 504 formed on the front side of board 300, for example, in first metallization level 312. Other connection pads 502 are connected to contacting elements 112 by conductive tracks 504 formed on the front side and by conductive tracks (not shown) formed on the back side of board 300, these tracks being connected to one another by conductive vias 506.

Contacting elements 112 form together a connector 508 enabling to convey up to 96 independent paths, or 48 differential paths.

Holes 510 may be provided in board 300 to ensure a mechanical hold or a grounding of support 108.

The arrangement of the contacting elements of board 300 enables to minimize the width of support 108. A more compact support 108 is thus obtained, which facilitates its use in a cryogenic environment, in particular its passage through the port of a cryostat.

Although FIG. 5 shows an example where support 108 comprises some hundred contacting elements 112, it will be within the abilities of those skilled in the art to provide a larger number of contacts 112, for example, by decreasing the width of tracks 504 and by increasing the number of layers of board 300.

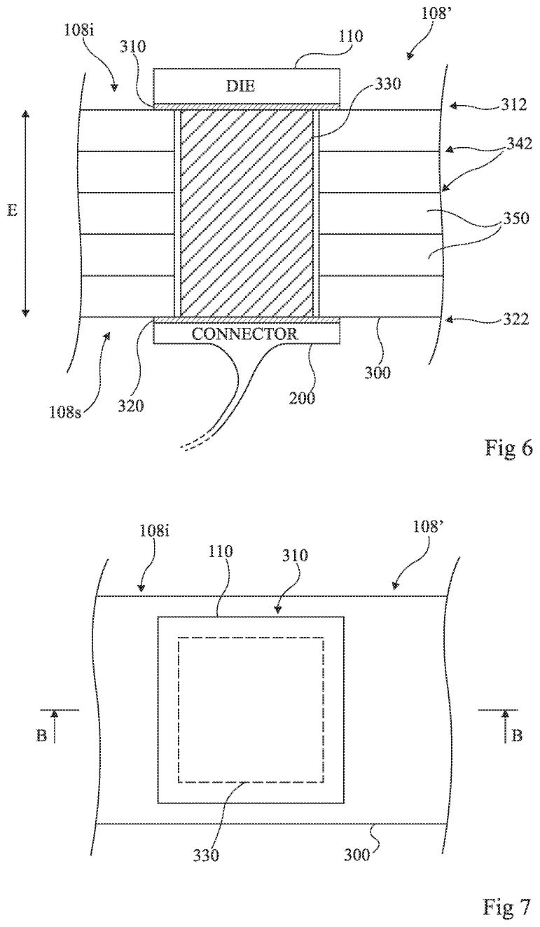

FIG. 6 is a partial simplified cross-section view of another embodiment of an electronic die support 108′.

The support 108′ of FIG. 6 comprises elements common with the support 108 of FIG. 3. These common elements will not be detailed again hereafter.

The support 108′ of FIG. 6 differs from the support 108 of FIG. 3 mainly in that support 108′ comprises a single via 330 connecting first region 310 to second region 320. One of the advantages of the embodiment discussed in relation with FIG. 6 is to allow a significant decrease in the thermal resistance between die 110 and thermal connector 200, while preserving the mechanical hold ensured by support 108′.

According to the shown embodiment, board 300 comprises intermediate levels 342 separated by insulating layers 350. However, the via 330 of support 108′ contacts no third region formed in an intermediate metallization level. Via 330 and regions 310 and 320 may be made of a same material, preferably copper.

According to another embodiment, a so-called “double-sided” printed circuit board, in other words, a board having no third metallization levels, interposed first metallization level 312 and second metallization 322, is used. First level 312 and second level 322 are in this case separated by a single insulating layer 350.

FIG. 7 is a partial simplified top view of the embodiment of electronic die support 108′ discussed in relation with FIG. 6. FIG. 6 corresponds, for example, to a cross-section along plane BB of FIG. 7.

According to a preferred embodiment, the conductive via 330 of support 108′ has, in top view in FIG. 7, a cross-section of substantially square shape. As illustrated in FIG. 7, via 330 is inscribed within the square formed by die 110 and within the square formed by first region 310.

The position, the dimensions, and/or the geometry of the conductive via 330 of support 108′ are designed to optimize the cooling of die 110. In particular, the cross-section of the conductive via 330 of support 108′ may be adjusted according to thermal and/or mechanical performance to be obtained. In the case of hollow conductive vias 330, the dimensions of these vias may further be adjusted to obtain a cryogenic fluid flow rate generating a heat transfer adapted to the cooling of die 110.

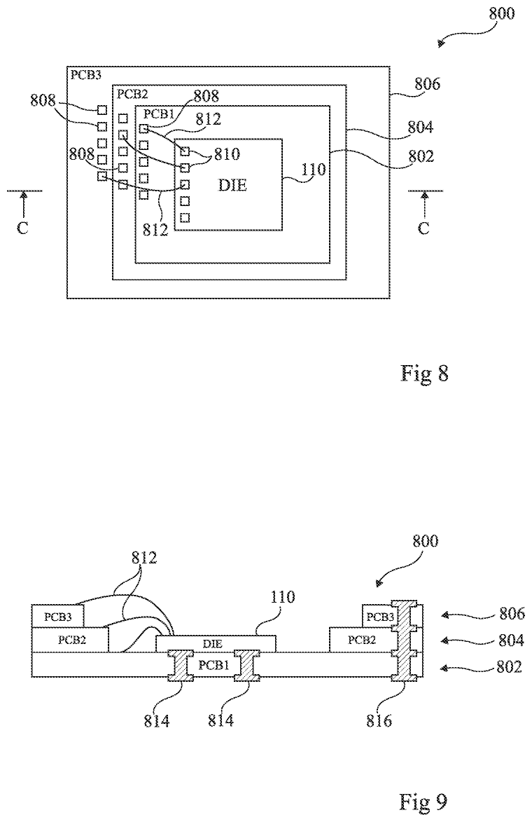

FIG. 8 is a partial simplified top view of still another embodiment of an electronic die support 800. FIG. 9 is a cross-section view, along plane CC of FIG. 8, of electronic die support 800.

In the shown example, support 800 comprises three stacked printed circuit boards 802 (PCB1), 804 (PCB2), and 806 (PCB3). Board 804 partially covers the upper surface of board 802. Board 806 partially covers the upper surface of board 804. More precisely, board 804 has a central rectangular-shaped cutting exposing a portion of the upper surface of board 802. In the shown example, board 806 also has a central rectangular-shaped cutting of dimensions greater than the opening of board 804, exposing a portion of the upper surface of board 804.

In the shown example, die 110 is on top of and in contact with the upper surface of board 802, inside of the cutting of board 804. The cuttings of boards 804 and 806 are for example substantially centered with respect to die 110.

In the shown example, the exposed portions of the upper surfaces of boards 802, 804, and 806 comprise contacting elements 808, for example, connection pads. The upper surface of die 110 for example comprises contacting elements 810, for example, connection pads. The contacting elements 810 of die 110 are for example connected to the contacting elements 808 of boards 802, 804, and 806 by conductive wires 812.

In the shown example, the board 802 intended to receive die 110 comprises conductive vias 814. Vias 814 are for example similar to the vias 330 previously described in relation with FIG. 3. Vias 814, which may be hollow to allow the passage of the cryogenic, for example, superfluid, fluid, and thus increase heat transfers, are for example located vertically in line with die 110. Although this is not shown, a connector is for example placed on the lower surface side of board 802, in contact with vias 814, so as to cool die 110.

As illustrated in FIG. 9, support 800 may comprise one or a plurality of other vias 816. Vias 816 for example extend from the upper surface of board 804 or of board 806 to the lower surface of board 802.

An advantage of support 800 lies in the fact that the stack of printed circuit boards 802, 804, 806 enables to provide a number of contacts 808 larger than in the case of a support comprising a single printed circuit board. As compared with the support 108 previously described in relation with FIG. 5, support 800 enables to have an even larger number of contact while keeping substantially identical external dimensions. As an example, support 800 may comprise approximately two hundred contacts 808 per board, that is, approximately six hundred contacts 808 as a whole.

Although an example where support 800 comprises a stack of three boards 802, 804, and 806 has been shown, it will be within the abilities of those skilled in the art to adapt the number of boards of the stack of support 800, for example, according to the number of contacts 810 of die 110.

Various embodiments and variants have been described. Those skilled in the art will understand that certain features of these various embodiments and variants may be combined, and other variants will occur to those skilled in the art. In particular, the forming of a support enabling to receive a plurality of dies and/or a plurality of thermal connectors on a same printed circuit board is within the abilities of those skilled in the art based on the above indications.

Further, it will be within the abilities of those skilled in the art to combine the embodiments of support 108, 108′ described in relation with FIGS. 3 to 7 with the embodiment of support 800 described in relation with FIGS. 8 and 9.

Finally, the practical implementation of the described embodiments and variations is within the abilities of those skilled in the art based on the functional indications given hereabove. In particular, the sizing and the distribution of conductive vias 330 vertically in line with the die 110 to be cooled is within the abilities of those skilled in the art based on the above indications.

1. Support for an electronic die comprising:
a first printed circuit board;
a first conductive region, intended to receive the die, located on a first surface of the first board;
a second conductive region, intended to receive a thermal connector, located on a second surface of the first board, opposite to the first surface; and
one or a plurality of third conductive regions, preferably four third conductive regions, interposed between the first region and the second region, the first region being connected to the second region by at least one through conductive via, located vertically in line with the first region, the via further connecting the third regions to one another.

2. Support for an electronic die according to claim 1, wherein the via is filled with a thermally-conductive material.

3. Support for an electronic die according to claim 1, wherein the via is hollow and has lateral walls coated with a thermally-conductive material.

4. Support for an electronic die according to claim 1, wherein the die is a die adapted to operating at cryogenic temperatures, preferably a die comprising superconductive circuits.

5. Support for an electronic die according to claim 1, wherein:
the first region is formed in a first metallization level, located on the first surface of the first board;
the second region is formed in a second metallization level, located on the second surface of the first board; and
each third region is formed in a third distinct metallization level, located between the first and second surfaces of the first board.

6. Support for an electronic die according to claim 5, wherein stacked metallizations levels are separated by an insulating layer.

7. Support for an electronic die according to claim 6, wherein the first region has a surface area of approximately 50 mm².

8. Support for an electronic die according to claim 7, wherein the first board comprises approximately one hundred first elements for contacting the die.

9. Support for an electronic die according to claim 8, wherein the first contacting elements are located on a same side of the first board, with respect to the first region.

10. Support for an electronic die according to claim 1, wherein the first board, of a substantially rectangular shape, has a length of approximately 12 cm and a width of approximately 3 cm.

11. Support for an electronic die according to claim 1, further comprising at least one second printed circuit board, stacked to the first board.

12. Support according to any of claims 11, wherein each second board comprises second contacting elements intended to be connected to third contacting elements of the die by conductive wires.

13. A system including at least one support according to claim 1, comprising:
at least one electronic die, adapted to operating in a cryogenic environment;
at least one cold source; and
at least one thermal connector, connecting the support to the cold source.
